(19) United States
(12) Patent Application Publication
(10) Pub. No.: US 2014/0210455 A1
(43) Pub. Date: Jul. 31, 2014

(54) VOLTAGE TAP DEVICE

(71) Applicant: Marvin Dee Allgood, Gambrills, MD (US)

(72) Inventor: Marvin Dee Allgood, Gambrills, MD (US)

(21) Appl. No.: 14/165,729

(22) Filed: Jan. 28, 2014

Related U.S. Application Data
(60) Provisional application No. 61/757,543, filed on Jan. 28, 2013.

(51) Int. Cl. G01R 1/067

(52) U.S. Cl. CPC G01R 1/067
USPC 324/126

(57) ABSTRACT

A voltage tap device is provided. The voltage tap device includes a housing. A tap needle may be protruding from the housing. A fuse is electrically connected to the tap needle. The housing may further include an input that is configured to receive a meter wire. The input is electrically connected with the fuse. Therefore, a user may attach the housing to an insulated conductor, pierce the insulation with the needle so the needle is in contact with the conductor, attach a meter wire to the input and determine the voltage level of the insulated conductor.

### CROSS-REFERENCE TO RELATED APPLICATION

This application claims the benefit of priority of U.S. provisional application No. 61/757,543, filed Jan. 28, 2013, the contents of which are herein incorporated by reference.

### BACKGROUND OF THE INVENTION

The present invention relates to a voltage tap device and, more particularly, to a device that is attached to an insulated conductor to obtain a sample of the voltage of the conductor.

Currently, obtaining a fused connection to an insulated conductor is difficult and expensive. Devices that are used in the field are large, difficult to install, expensive, and require a separate fuse.

As can be seen, there is a need for an improved device that provides for a fused connection with an insulated conductor.

### SUMMARY OF THE INVENTION

In one aspect of the present invention, a voltage tap device comprises: a housing comprising a top portion, a bottom portion, a front end and a rear end, wherein the housing is attachable to an insulated conductor; a tap needle protruding from the housing; a fuse electrically connected to the tap needle; and an input to the housing configured to receive a meter wire, wherein the input is electrically connected to the fuse.

In another aspect of the present invention, a method of determining the voltage of an insulated conductor comprises: providing a voltage tap device comprising a housing comprising a tap needle protruding from the housing; inserting the tap needle through the insulation and into the conductor portion of the insulated conductor; connecting a fuse to the tap needle; and connecting a meter wire to the output side of the fuse, thus providing a sample of the main conductor's voltage to a meter or other device.

These and other features, aspects and advantages of the present invention will become better understood with reference to the following drawings, description and claims.

### BRIEF DESCRIPTION OF THE DRAWINGS

FIG. 1 is a perspective view of the present invention shown in use;

FIG. 2 is a perspective view of the present invention shown in use with multiple items shown in cutaway for illustrative clarity;

FIG. 3 is a side view of the present invention;

FIG. 4 is a front view of the present invention;

FIG. 5 is a top view of the present invention;

FIG. 6 is a bottom perspective view of the present invention;

FIG. 7 is a section detail view of the present invention along line 7-7 in FIG. 1;

FIG. 8 is an exploded view of the present invention; and

FIG. 9 is a perspective view of an alternate embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

The present invention includes a device that quickly and safely taps the voltage on any insulated conductor. The present invention allows for a quick, easy and safe way to obtain a fused connection with an insulated conductor, without the requirement of turning off the power. This provides the voltage of the main conductor so that when connected to the proper meter device the power being delivered by the main conductor can be accurately measured. The present invention is a small and inexpensive device that can be easily and quickly clamped directly to any insulated conductor using standard cable ties. In certain embodiments, the present invention facilitates for easily installation and replacement of a potentially blown fuse.

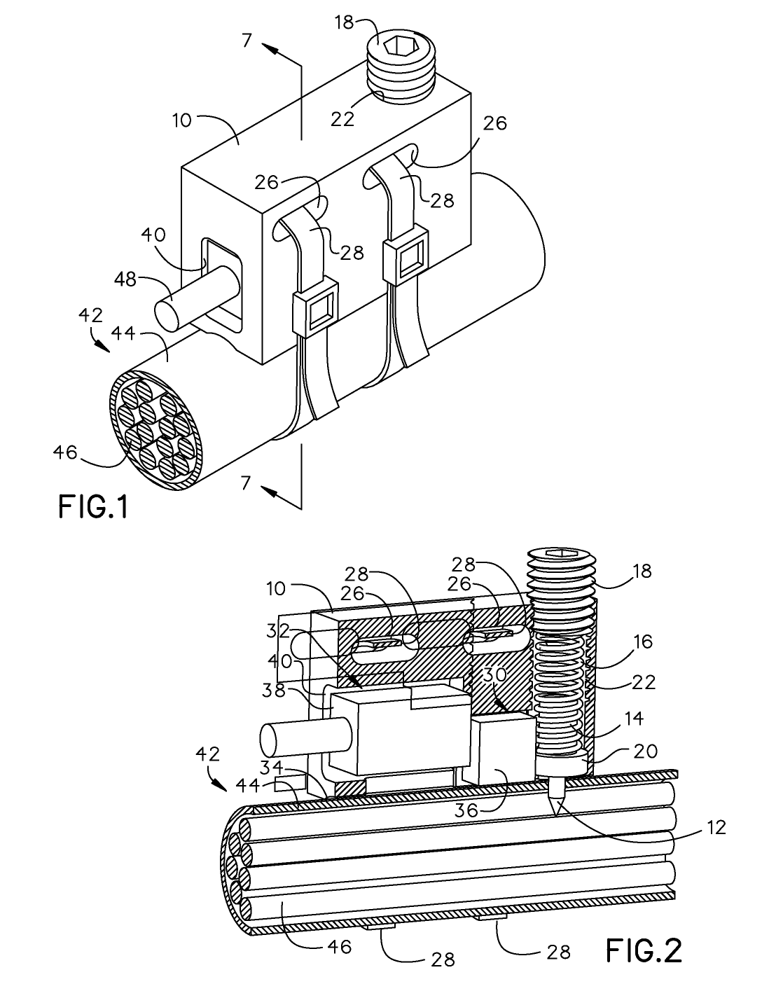

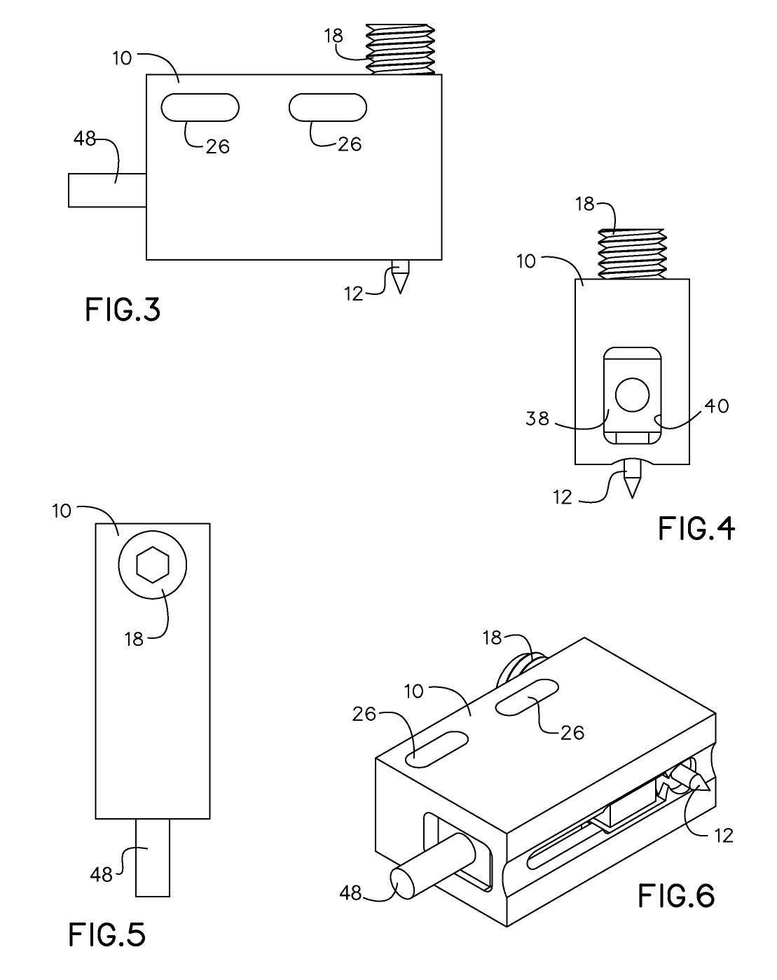

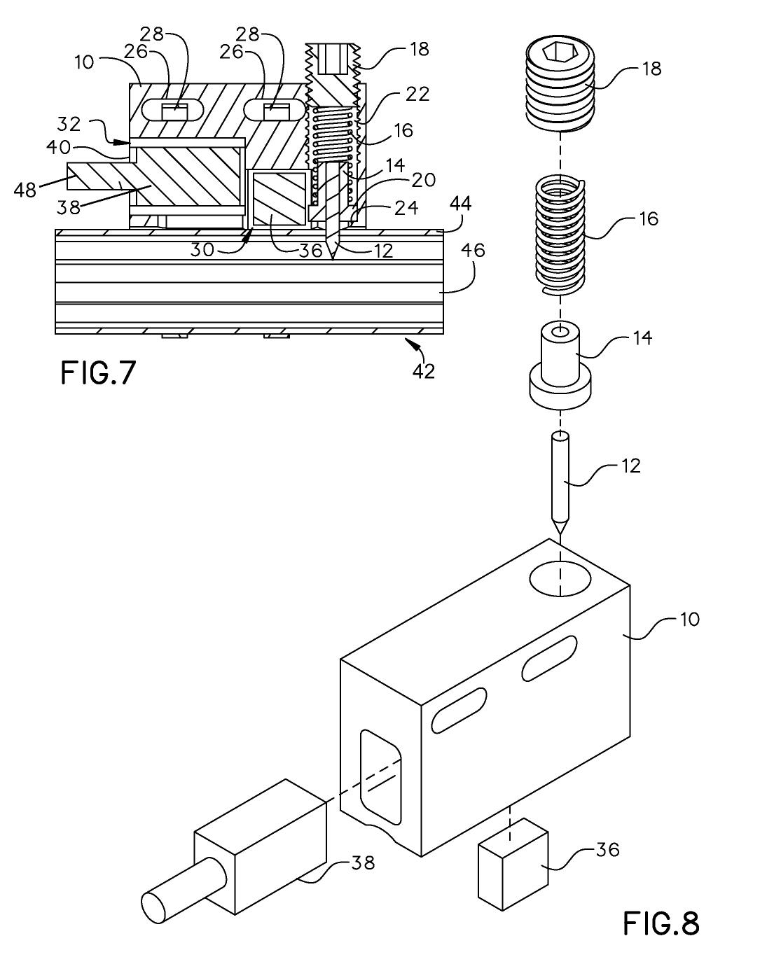

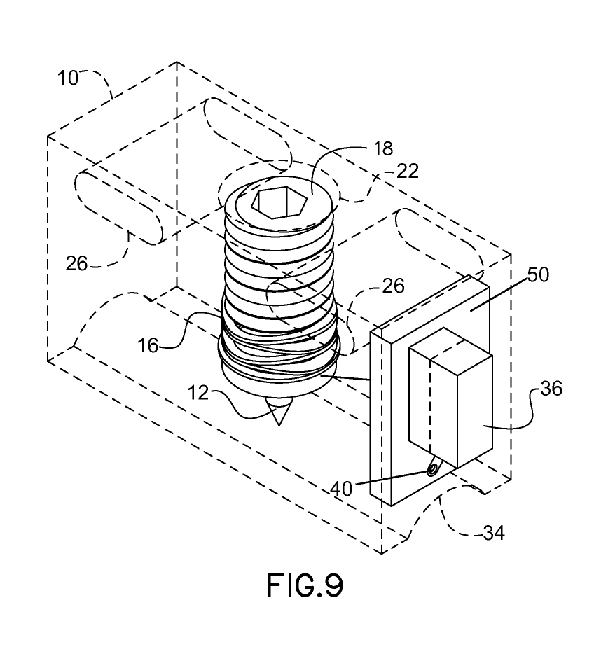

Referring to FIGS. 1 through 9, the present invention includes a voltage tap device. The voltage tap device includes a housing 10. A tap needle 12 may be protruding from the housing 10. In certain embodiments, a fuse 36 is electrically connected to the tap needle 12. The housing 10 may further include an input 40 that is configured to receive a meter wire 48. The input 40 is electrically connected with the fuse 36. Therefore, a user may attach the housing 10 to an insulated conductor 42, pierce the insulation 44 with the needle 12 so the needle 12 is in contact with the conductor 46, attach a meter wire 48 to the input 40 and determine the voltage level of the insulated conductor 42.

The housing 10 may contain the other components of the present invention. Further, the housing 10 may be directly attached to the insulated conductor 42. In certain embodiments the housing 10 may include securing slots 26. Straps 28 or zip ties may run through the securing slots 26 and wrap around the insulated conductor 42. Therefore, the straps 28 may releasably connect the housing 10 to the insulated conductor 42. In alternate embodiments, an additional housing 10 may be placed on the opposite side of the insulated conductor 42 and screws may be used to hold the housings 10 together. The present invention is not limited to the above mentioned connectors and any suitable connector may be used.

In certain embodiments, the housing 10 may include a top portion, a bottom portion, a front end, and a rear end. The tap needle 12 may protrude from the bottom portion of the housing 10. In certain embodiments, the bottom portion may include a formed channel 34 that is shaped to fit the insulated conductor 42 within. Therefore, a user may easily place the formed channel 34 onto the insulated conductor 42 and pierce the insulation 44 with the tap needle 12.

In certain embodiments, the tap needle 12 may be retractable and extendable from the housing 10. In such embodiments, the present invention may include a piercing component including tap needle 12, a tap needle holder 14, a spring 16 and a male set screw 18. In such embodiments, the housing 10 may include a threaded opening 22 through the top portion and bottom portion. The tap needle 12 may be attached to the tap needle holder 14. The holder 14 may include a flange and the threaded opening 22 of the housing 10 may include a lip 24 near the bottom portion. The flange may rest against the lip 24, allowing the needle 12 to protrude a limited distance from the housing 10. The spring 16 may fit over the holder 14 and the male set screw 18 may be on top of the spring 16 and accessible from the top portion of the opening 22. The spring 16 may secure the needle to the insulated conductor 44 so that the needle may remain secure even during movement of the insulated conductor 44. Therefore, a user may rotate the male set screw 18 to extend and retract the tap needle 12.

As mentioned above, the present invention may include a fuse 36. The fuse 36 electrically connects with the tap needle 12. The fuse 36 is used to protect the electrical circuit from over current conditions. The fuse 36 may electrically connect the tap needle 12 to the meter wire 48. In certain embodiments, the fuse 36 may be attached within the housing 10 of the present invention. In certain embodiments, the fuse 36 may be releasably attachable to the housing 10 for easy access and replacement.

In certain embodiments, the meter wire 48 may be connected to a connector 38 that has a male and female portion. In such embodiments, the housing 10 may include a connector cavity 32. At least the female portion of the connector 38 may fit within the connector cavity 32 and electrically connect with the fuse 36. The fuse 36 may already be electrically connected to the tap needle 12 and may be positioned within a fuse cavity 30 within the housing. Therefore, a user may attach the housing 10 to the insulated conductor 46, pierce the insulator 44 with the needle, and place the male portion of the connector 38 within the female portion of the connector 38 mating it with the female portion of the connector 38 thus providing the voltage within the insulated conductor 46 to the meter wire 48 that is connected to the male portion of the connector 38.

In certain embodiments, the present invention may include a printed circuit board 50. The printed circuit board 50 may be electrically connected with the tap needle 12. The printed circuit board 50 may include the meter wire input 40 as well as an input for the fuse 36. Therefore, a user may attach the housing 10 to the insulated conductor 46 and pierce the insulator 44 with the needle. The user may then attach the meter wire 48 to the meter wire input 40. To complete the electric connection, the user may then attach the fuse 36 to the printed circuit board 50, which electrically connects the tap needle 12 to the meter wire 48.

In alternative embodiments, the needle 12 may be forced through the insulation 44 with an insulated set screw. Therefore, the needle 12 and the needle holder 14 do not need to be threaded and the needle 12 may be set at a safe depth without the use of an insulated screwdriver. In alternate embodiments, fuse 36 may be soldered to the load wire 48 which is then connected to the load using a wire nut or similar device.

A method of determining the voltage of an insulated conductor may comprise: providing a voltage tap device comprising a housing comprising a tap needle protruding from the housing; inserting the tap needle through the insulation and into the conductor portion of the insulated conductor; connecting a fuse to the tap needle; and connecting a meter wire to the fuse. The method may further include the step of inserting a connector connected to the meter wire into the housing, wherein the connector connects with the fuse within the housing

The present invention may be used in any circumstance where it is desired to provide a small amount of power from a large conductor. For example, when a user is metering the power being delivered by a large circuit, the voltage of the large circuit needs to be obtained by the meter. This often requires a circuit breaker panel or a large insulation piercing device and a large fuse holder and fuse. The present invention may be easily attached to the large conductor with one or two cable ties, wire nutting the meter to the present invention and adjusting the needle probe until it is in contact with the main cable.

It should be understood, of course, that the foregoing relates to exemplary embodiments of the invention and that modifications may be made without departing from the spirit and scope of the invention as set forth in the following claims.

What is claimed is:

1. A voltage tap device comprising:
a housing comprising a top portion, a bottom portion, a front end and a rear end, wherein the housing is attachable to an insulated conductor;
a tap needle protruding from the housing;
a fuse electrically connected to the tap needle; and
an input to the housing configured to receive a meter wire, wherein the input is electrically connected to the fuse.

2. The voltage tap device of claim 1, wherein the fuse is releasably attachable to the housing.

3. The voltage tap device of claim 2, further comprising a printed circuit board electrically connected with the tap needle within the housing, wherein the printed circuit board comprises the input to receive the meter wire, and comprises a fuse input, wherein the fuse is releasably attachable to the fuse input, and wherein the fuse completes the electric connection between the input and the tap needle.

4. The voltage tap device of claim 1, wherein the tap needle is retractable into the housing.

5. The voltage tap device of claim 4, wherein the housing comprises a threaded opening running from the top portion to the bottom portion and formed to house the tap needle.

6. The voltage tap device of claim 5, further comprising a male set screw protruding from the top portion and extending into the threaded opening, a spring connecting the male set screw and the tap needle, wherein the male set screw is rotated to retract and extend the needle from the housing.

7. The voltage tap device of claim 5, further comprising a connector port configured to receive a connector, wherein the connector electrically connects the fuse and the meter wire.

8. The voltage tap device of claim 1, wherein the housing further comprises slots configured to receive at least one strap to secure the housing to the insulated conductor.

9. A method of determining the voltage of an insulated conductor comprising:
providing a voltage tap device comprising a housing comprising a tap needle protruding from the housing;
inserting the tap needle through the insulation and into the conductor portion of the insulated conductor;
connecting a fuse to the tap needle; and
connecting a meter wire to the fuse.

10. The method of claim 9 further comprising the step of inserting a connector connected to the meter wire into the housing, wherein the connector connects with the fuse within the housing.
